(19) United States
(12) Patent Application Publication
(10) Pub. No.: US 2018/0042144 A1
(43) Pub. Date: Feb. 8, 2018

(54) Method of Cooling Electric-Vehicle Controller

(71) Applicants: Kuei-Piao Lee, Taipei (TW); Yung-Tzu Chuang, Taipei (TW)

(72) Inventor: Kuei-Piao Lee, Taipei (TW)

(21) Appl. No.: 15/227,140

(22) Filed: Aug. 3, 2016

(51) Int. Cl. H05K 7/20

(52) U.S. Cl. CPC H05K 7/20854

(57) ABSTRACT

A method is provided to dissipate heat for an electric-vehicle controller. A heat-dissipation case having a hollow shape is obtained. The controller is put in the case. A few first heat-sink strips are set on at least one surface of the controller. A few second heat-sink strips are also set on at least one surface of the controller. An end of each of the second heat-sink strips is contacted with an inner surface of the case. Thus, with coordination of the heat-sink strips and the case, heat of the controller is directed out the case. The present invention has a simple structure, has good heat dissipation, reduces production cost and reduces controller volume.

### TECHNICAL FIELD OF THE INVENTION

The present invention relates to heat dissipation for a controller; more particularly, relates to directing heat to a heat-dissipation case to achieve a simple structure, obtain good heat dissipation, reduce production cost and reduce controller volume.

### DESCRIPTION OF THE RELATED ART

A conventional controller for an electric vehicle will generate heat during operation. If the heat is not dissipated immediately, normal operation of the controller will be affected, or the controller may be even burnt. Therefore, the controller must be set with a cooling device for dissipating the heat generated during operation. A common method is to set aluminum blocks, heat pipes, and/or fans on the controller to further control the heat dissipation for the controller.

However, the above method for heat dissipation uses a complex structural design, and must reserve predetermined space for the aluminum blocks, heat pipes, and/or fans, while the aluminum blocks, heat pipes, and/or fans would make production cost higher.

Hence, the prior art does not fulfill all users' requests on actual use.

### SUMMARY OF THE INVENTION

The main purpose of the present invention is to direct heat which is generated on using an electric-vehicle controller to a heat-dissipation case by first heat-sink strips and second heat-sink strips, where the present invention has a simple structure, has good heat dissipation, reduces production cost and reduces controller volume.

To achieve the above purpose, the present invention is a method of cooling an electric-vehicle controller, comprising steps of: (a) obtaining a heat-dissipation case having a hollow shape; (b) setting an electric-vehicle controller in the heat-dissipation case; (c) setting a plurality of first heat-sink strips on at least a surface of the electric-vehicle controller; and (d) setting a plurality of second heat-sink strips on at least a surface of the electric-vehicle controller to contact an end of each of the second heat-sink strips with an inner surface of the heat-dissipation case. Accordingly, a novel method of cooling an electric-vehicle controller is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the flow view showing the preferred embodiment according to the present invention;

FIG. 2 is the view showing the first state-of-use of the preferred embodiment;

FIG. 3 is the view showing the second state-of-use; and

FIG. 4 is the view showing the third state-of-use.

### DESCRIPTION OF THE PREFERRED EMBODIMENT

The following description of the preferred embodiment is provided to understand the features and the structures of the present invention.

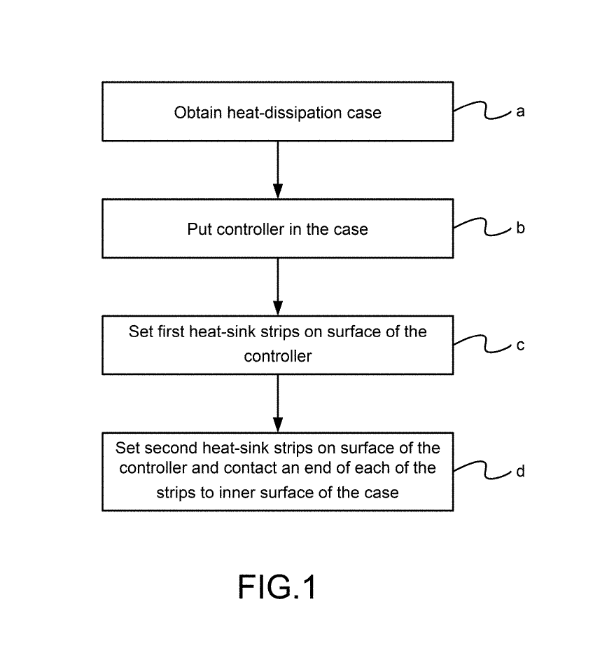

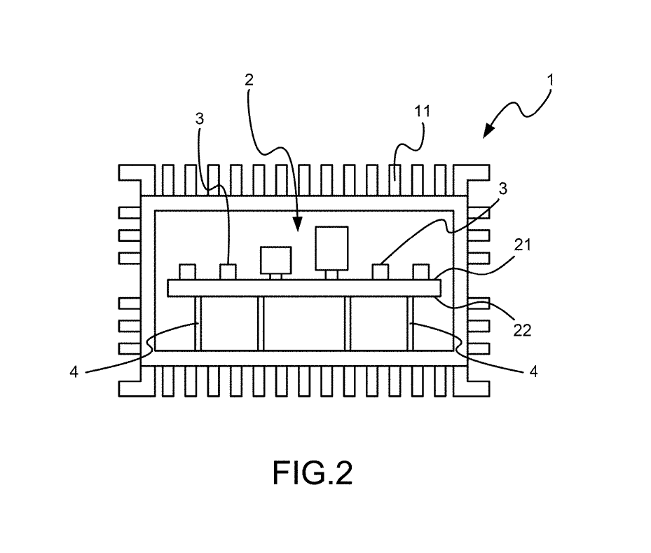

Please refer to FIG. 1 and FIG. 2, which are a flow view showing a preferred embodiment according to the present invention; and a view showing a first state-of-use of the preferred embodiment. As shown in the figures, the present invention is a method of cooling an electric vehicle controller, comprising the following steps:

(a) A heat-dissipation case 1 having a hollow shape is obtained. The heat-dissipation case 1 is made through aluminum extrusion and has a plurality of heat-dissipation fins 11 at an outer side. A spacing between every adjacent two of the heat-dissipation fins 11 is 2 millimeters (mm)˜50 mm while 25 mm is preferred.

(b) An electric-vehicle controller 2 is set in the heat-dissipation case 1. The electric-vehicle controller 2 has a top surface 21 and a bottom surface 22.

(c) A plurality of first heat-sink strips 3 are set on the top surface 21 of the electric-vehicle controller 2. The first heat-sink strips 3 are made of copper; and each of the first heat-sink strips 3 has a diameter of 1 mm˜10 mm while 5 mm is preferred.

(d) A plurality of second heat-sink strips 4 are set on the bottom surface 22 of the electric-vehicle controller 2. An end of each of the second heat-sink strips 4 is contacted with an inner surface of said heat-dissipation case. Therein, the second heat-sink strips 4 are made of copper; and each of the second heat-sink strips 4 has a diameter of 3 mm˜20 mm while 15 mm is preferred.

Thus, a novel method of cooling an electric vehicle controller is obtained.

When heat is generated on operating the electric vehicle 2, the first heat-sink strips 3 and the second heat-sink strips 4 separately absorb the heat on the electric vehicle 2. Then, the heat is directed to the heat-dissipation case 1 to be dissipated through the heat-dissipation fins 11. The part of heat absorbed by the first heat-sink strips 3 is directly dissipated without using fans. Thus, the present invention has a simple structure, has good heat dissipation, reduces production cost and reduces controller volume.

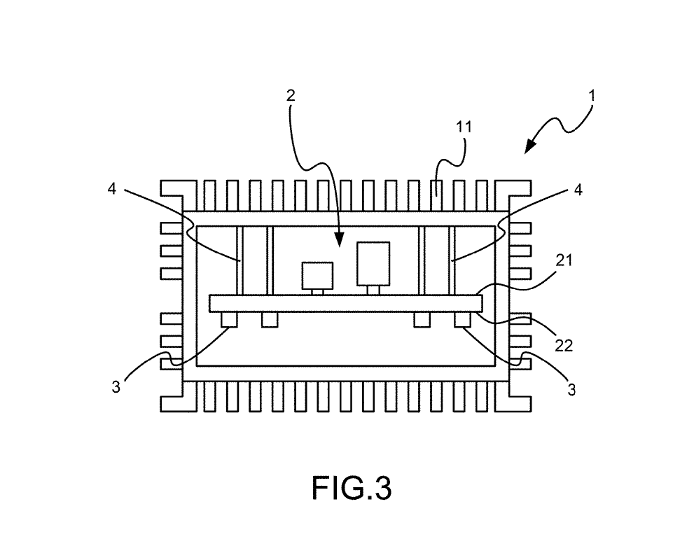

Please further refer to FIG. 3, which is a view showing a second state-of-use. As shown in the figure, the first heat-sink strips 3 can be set on the bottom surface 22 of the electric-vehicle controller 2 while the second heat-sink strips 4 are set on the top surface 22 of the electric-vehicle controller 2.

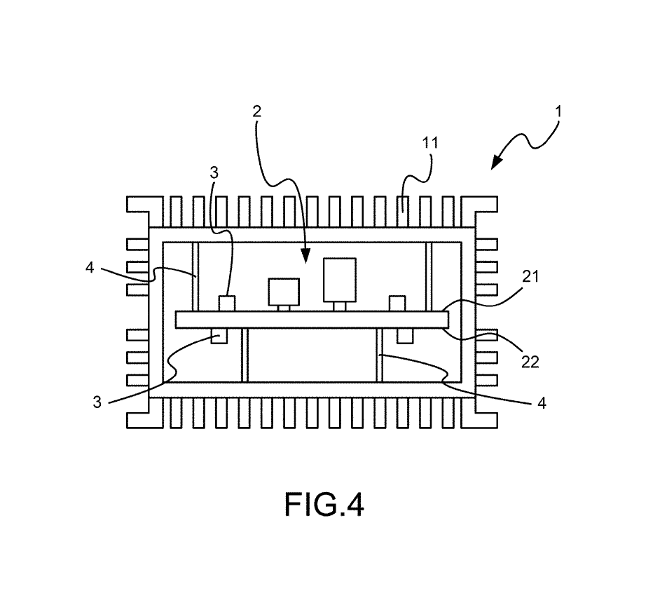

Please further refer to FIG. 4, which is a view showing a third state-of-use. As shown in the figure, the first heat-sink strips 3 can be set on the top surface 21 and the bottom surface 22 of the electric-vehicle controller 2 while the second heat-sink strips 4 are also set on the top surface 21 and the bottom surface 22 of the electric-vehicle controller 2. Yet, each of the first heat-sink strips 3 is located adjacent to one of the second heat-sink strips 4. Therein, a spacing between every two adjacent ones of the first heat-sink strips 3 and the second heat-sink strips 4 is 2.5 mm˜60 mm while 30 mm is preferred. Thus, the heat is directed to the heat-dissipation case 1 through the first heat-sink strips 3 and the second heat-sink strips 4 on the top surface 21 and the bottom surface 22 of the electric-vehicle controller 2 for increasing heat-dissipation speed.

To sum up, the present invention is a method of cooling an electric-vehicle controller, where heat generated on using the electric-vehicle controller is directed to a heat-dissipation case by first heat-sink strips and second heat-sink strips; and, thus, the present invention has a simple structure, has good heat dissipation, reduces production cost and reduces controller volume.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of cooling an electric-vehicle controller, comprising steps of:
(a) obtaining a heat-dissipation case having a hollow shape;
(b) locating an electric-vehicle controller in said heat-dissipation case;
(c) locating a plurality of first heat-sink strips on at least a surface of said electric-vehicle controller; and
(d) locating a plurality of second heat-sink strips on at least a surface of said electric-vehicle controller to contact an end of each of said second heat-sink strips with an inner surface of said heat-dissipation case.

2. The method according to claim 1,
wherein, in step (a), said heat-dissipation case is made through aluminum extrusion and has a plurality of heat-dissipation fins at an outer side of said heat-dissipation case.

3. The method according to claim 2,
wherein a spacing between every two adjacent ones of said heat-dissipation fins is 2 millimeters (mm)˜50 mm while 25 mm is preferred.

5. The method according to claim 1,
wherein, in step (c) and step (d), said first and said second heat-sink strips are made of copper; each of said first heat-sink strips has a diameter of 1 mm˜10 mm while 5 mm is preferred; and each of said second heat-sink strips has a diameter of 3 mm˜20 mm while 15 mm is preferred.

6. The method according to claim 1,
wherein said first heat-sink strips are located on a top surface of said electric-vehicle controller and said second heat-sink strips are located on a bottom surface of said electric-vehicle controller.

7. The method according to claim 1,
wherein said first heat-sink strips are located on a bottom surface of said electric-vehicle controller and said second heat-sink strips are located on a top surface of said electric-vehicle controller.

8. The method according to claim 1,
wherein said first heat-sink strips are located on a top surface and a bottom surface of said electric-vehicle controller; said second heat-sink strips are located on said top surface and said bottom surface of said electric-vehicle controller; and each of said first heat-sink strips is located adjacent to one of said second heat-sink strips.

9. The method according to claim 1,
wherein a spacing between every two adjacent ones of said first heat-sink strips and said second heat-sink strips is 2.5 mm˜60 mm while 30 mm is preferred.
